(19) United States
(12) Patent Application Publication
(10) Pub. No.: US 2016/0081220 A1
(43) Pub. Date: Mar. 17, 2016

(54) Reduction of Intake Resistance for Air Flow Enhancement

(71) Applicant: Cisco Technology, Inc., San Jose, CA (US)

(72) Inventors: Vic Hong Chia, Sunnyvale, CA (US); Hong Tran Huynh, Fremont, CA (US); M. Baris Dogruoz, Sunnyvale, CA (US)

(21) Appl. No.: 14/485,943

(22) Filed: Sep. 15, 2014

(51) Int. Cl. H05K 7/20; F24F 7/007; H05K 9/00

(52) U.S. Cl. CPC H05K 7/20009; H05K 9/0007; F24F 7/007

(57) ABSTRACT

An apparatus includes a frame and one or more heat generating elements supported by the frame. A plurality of ports are located at the front portion of the frame, and are electrically coupled to the heat generating elements. A faceplate is coupled to the front portion of the frame and includes one or more port openings to allow access to the ports and a plurality of airflow openings. Each of the airflow openings has a bottom edge aligned with the front portion of the frame and a top edge aligned with the top portion of the frame. The top edges of the airflow openings are set back a predetermined distance from the front portion of the frame.

### TECHNICAL FIELD

The present disclosure relates to airflow cooling of rack mounted electronics.

### BACKGROUND

In a front-to-back air cooling network rack, holes are strategically placed in the faceplate of network line cards to allow cooling air to enter the line cards. One design challenge is to provide sufficient cool air into the system with maximum input/output (I/O) ports and adequate electromagnetic interference (EMI) containment. As the performance of integrated circuits and processing power increases, the balance between port count and perforation size/area forces a tradeoff between switching capacity and thermal management. For a given footprint, such as a one rack unit (RU) line card, as the port density increases, the area available for perforations in the faceplate decreases, and less cool air is able to be drawn into the system.

### BRIEF DESCRIPTION OF THE DRAWINGS

FIG. 1A illustrates a perspective view of an electronics module according to an example embodiment.

FIG. 1B illustrates an exploded view of the electronics module according to an example embodiment.

FIG. 2A shows a perspective view of a faceplate portion of the electronics module according to an example embodiment.

FIG. 2B shows a side view of the faceplate portion according to an example embodiment.

FIG. 3 shows a side view of the front portion of the electronics module, illustrating the airflow into the module according to an example embodiment.

FIG. 4 shows an electronics rack with a plurality of electronics modules mounted therein according to an example embodiment.

FIG. 5 shows a side view of two electronics modules as mounted in the electronics rack according to an example embodiment.

FIG. 6 illustrates the pressure drop in the airflow according to an example embodiment.

FIG. 7 is a flow chart depicting an example process for using forced air cooling in an electronics rack according to an example embodiment.

### DESCRIPTION OF EXAMPLE EMBODIMENTS

### Overview

An apparatus is presented herein comprising a frame and one or more heat generating elements supported by the frame. A plurality of ports are located at the front portion of the frame, and are electrically coupled to the heat generating elements. A faceplate is coupled to the front portion of the frame and includes one or more port openings to allow access to the ports and a plurality of airflow openings. Each of the airflow openings comprises a bottom edge aligned with the front portion of the frame and a top edge aligned with the top portion of the frame The top edges of the airflow openings are set back a predetermined distance from the front portion of the frame.

### Example Embodiments

One factor in bringing cooling air through a faceplate in a rack mounted electronics system, such as a network line card, is the projected intake area. A higher projected intake area permits a lower pressure drop and a higher airflow rate through line cards mounted in a rack. One example of an intake area comprises slots stamped into the faceplate of the line card, e.g., above the ports of the line card. According to the techniques presented herein, the projected area is increased by retracting the top edge of the intake slots. In another example the projected area of stacked line cards (e.g., line cards mounted above and below each other in a rack) is increased by chamfering the bottom of the faceplate, which is aligned with the intake slots of the line card below.

The design of the faceplate described herein provides approximately a 20% improvement on the pressure drop at the intake due to the increased area of the intake slots. The chamfered bottom of the faceplate contributes approximately an additional 5% improvement. The electronics modules described herein fully utilize the effective intake area of the faceplate without sacrificing electromagnetic interference (EMI) performance. The faceplate allows maximum Input/Output (I/O) port count or signal capacity, while minimizing any thermal choking concerns. Additionally, the faceplate design described herein minimizes costs due to the lack of costly additional features, e.g., hex honeycomb air intake holes, custom EMI shielding gaskets, and/or computer numerical controlled (CNC) machining.

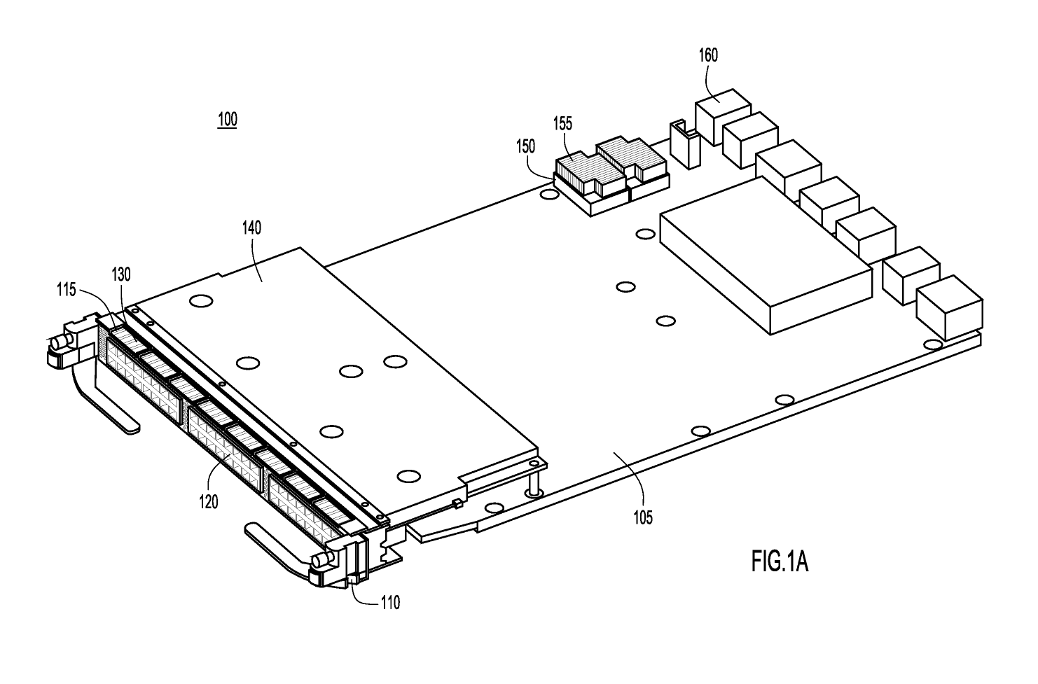

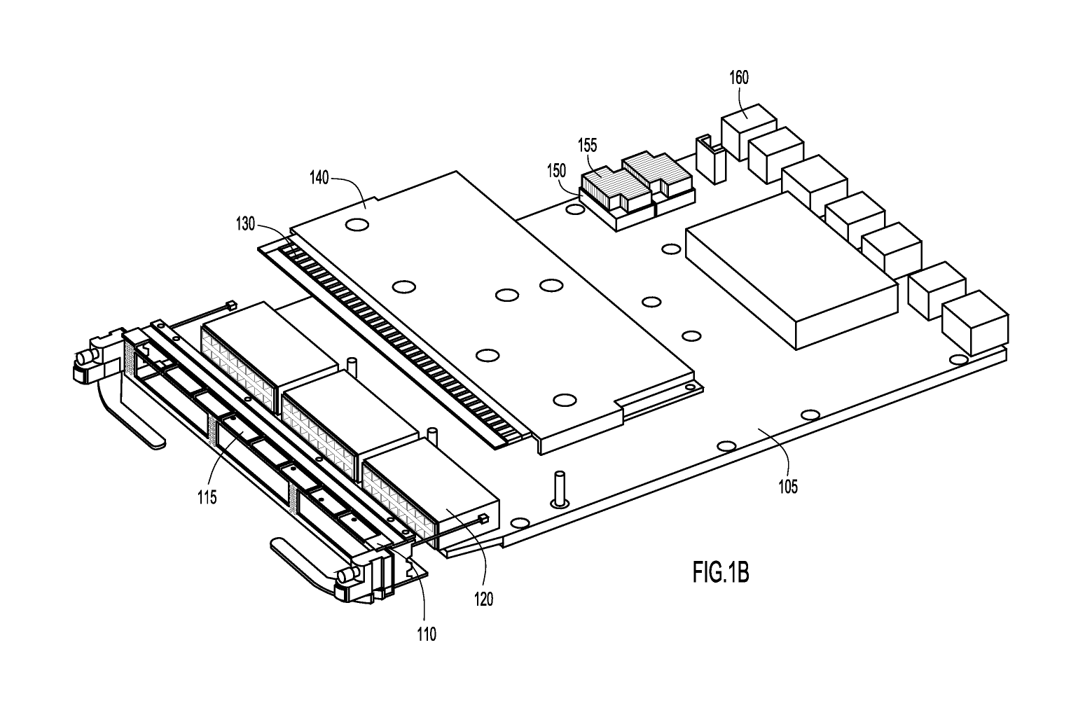

Referring to FIGS. 1A and 1B, an example of a rack-mountable electronics module 100 is shown. FIG. 1A shows a perspective view of an assembled electronics module 100 omitting the exterior cover, in order to better illustrate the interior components. FIG. 1B shows an exploded view of an electronics module 100 to illustrate the relationships and connections between individual elements of the electronics module 100. In these examples, the electronics module 100 is shown as a network line card, but any electronics modules that generate heat and are air-cooled may be used. Line card 100 comprises a printed circuit board (PCB) 105 coupled to a faceplate 110 at the front of the PCB 105. The faceplate 110 comprises a plurality of intake slots 115 along the top edge of the faceplate 110. A plurality of ports 120 are electrically connected to the PCB 105 and are accessed through holes in the faceplate 110. In one example, a dust shield 130 may keep debris in the cooling air from entering the interior of the line card 100 and potentially damaging the interior components.

An EMI shield 140 drops down onto the top of module over the ports 120 and prevents unacceptable levels of EMI from passing through the relatively large intake slots 115. The EMI shield 140 presses down against an EMI gasket on the inside front of the faceplate 110 and on top of the cage that surrounds the ports 120. Heat generating elements 150, such as a central processing unit (CPU), are coupled to the PCB 105. Heat sink 155 is placed in thermal contact with heat generating element 150 to provide a larger surface area for cooling air to interact with.

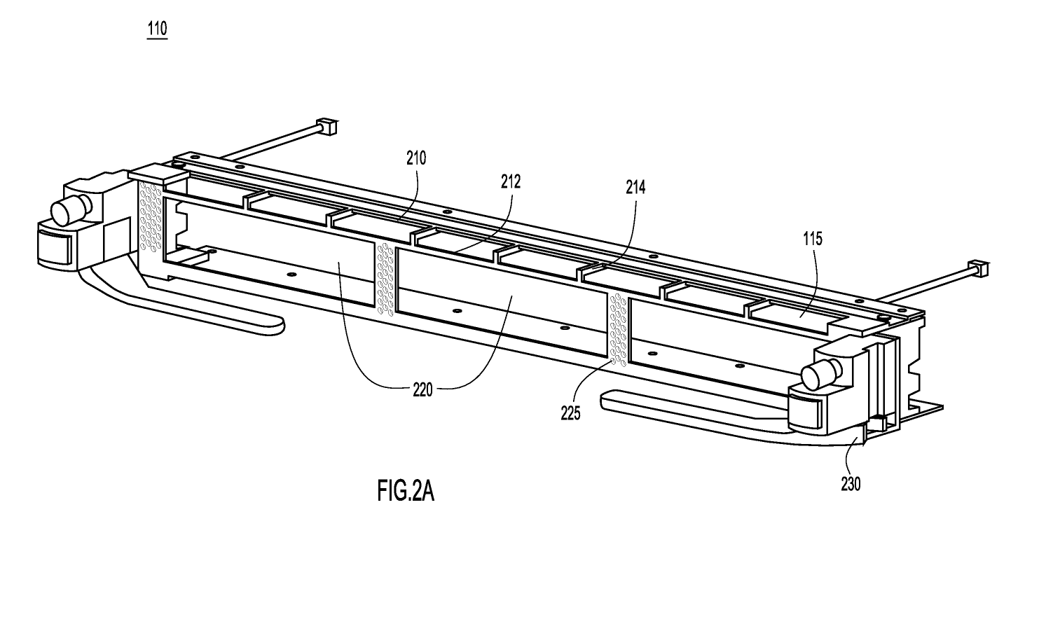

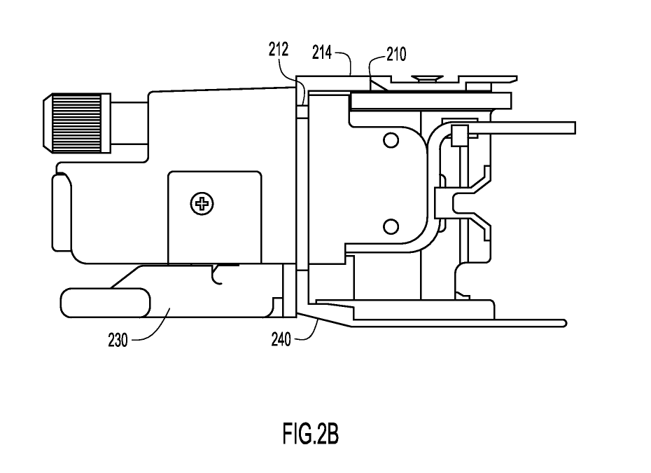

Referring to FIG. 2A, a faceplate 110 is shown separate from the line card 100. Faceplate 110 comprises a plurality of intake slots 115 located, in this example, at the corner where the top of the faceplate 110 meets the front of the faceplate 110. Each intake slot 115 is defined by a top edge 210, a bottom edge 212, and webbing 214 between two adjacent intake slots 115. The top edge 210 is disposed along a plane that substantially aligns with the top face of the faceplate 110 and the electronics module 100. The bottom edge 212 is disposed along a plane that substantially aligns with the front face of the faceplate 110 and the electronics module 100.

Faceplate 110 also includes one or more openings 220 to allow access to elements (e.g., ports 120) on the electronics module 100. Webbing 225 may provide structure for the faceplate 110 on the sides of the openings 220, and may include air intake holes to provide some cooling air into the electronics module 100. Rack-mount locking mechanisms 230 may be attached to the faceplate, and secure the faceplate 110 and the attached electronics module 100 to an electronics rack.

Referring to FIG. 2B, a side view of the faceplate 110 is shown. The side view shows the bottom edge 212 of the intake slot disposed along the front face of faceplate 110, with the rack-mount locking mechanism 230 extending from the front face. The top edge 210 of the intake slot is disposed along the top face and set back a predetermined distance from the front face of the faceplate 110. In one example, the top edge 210 of the intake slot is set back at least 0.75 inches from the front face of the faceplate 110. Setting the top edge 210 back from the front face of the faceplate 110 allows for a larger opening for air to enter the intake slots 115. The larger opening reduces the pressure drop and allows a greater volume of cooling air to enter the electronics module.

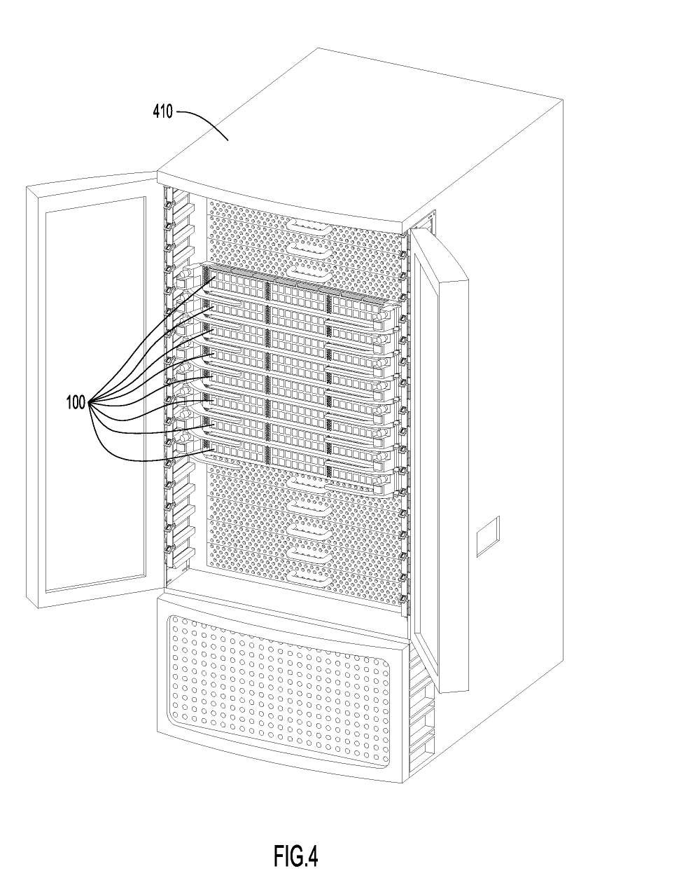

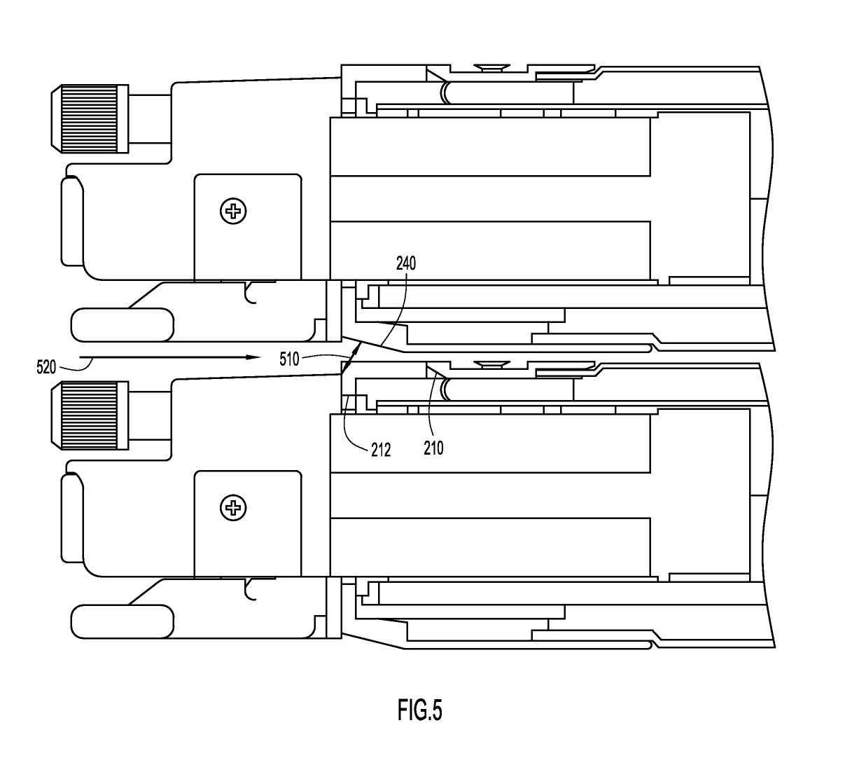

The corner where the front face of the faceplate 110 and the bottom face of the faceplate 110 is replaced with a chamfer 240 that extends from a predetermined point on the front face to a predetermined point on the bottom face. In one example, the chamfer 240 is a linear chamfer, extending from a point 0.1 inches up from the bottom face along the front face to a point 0.38 inches back from the front face along the bottom face. In other examples, the chamfer 240 may be a combination of multiple linear segments, or the chamfer 240 may be non-linear. The chamfer 240 allows a larger opening for air to enter an electronics module positioned below the current electronics module, as will be discussed below with respect to FIGS. 4 and 5.

In one example, the faceplate 110 shown in FIGS. 2A and 2B is formed from a metal plate with holes (e.g., intake slots 115, openings 220, holes in webbing 225, etc.) formed from simple operations (e.g., extruding, punching, etc.) with minimal or no use of complex machining operations (e.g., milling). The simple fabrication techniques enable the faceplate 110 to be constructed at a lower cost than faceplates manufactured with more complex fabrication techniques.

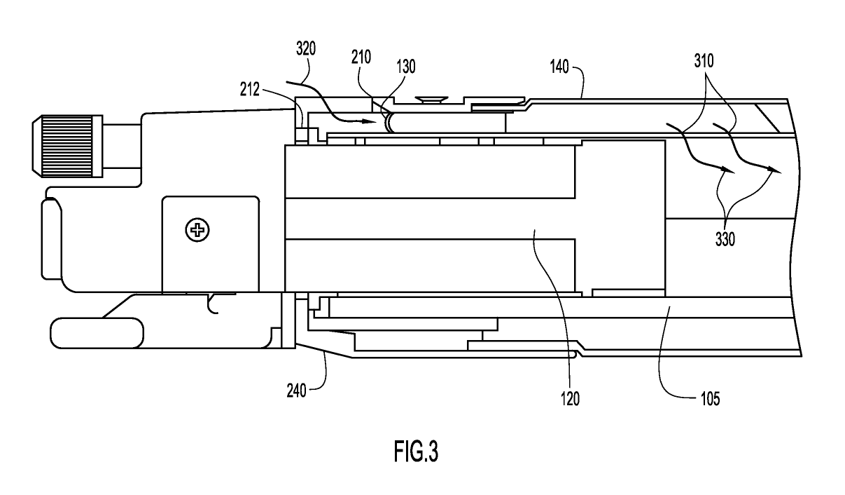

Referring to FIG. 3, a side view of an electronics module with the airflow into the module is shown. An electronics module is shown, including circuit board 105, intake slots defined by a top edge 210 and a bottom edge 212, ports 120, dust shield 130, and EMI shield 140. In this example, the EMI shield 140 comprises air holes 310 disposed to the rear of ports 120. Air flows in the intake slots as shown at 320, and travels through the dust shield 130 and EMI shield 140 before exiting the EMI shield into the interior of the electronics module as shown at 330. Once the cooling air has entered the interior of the electronics module, it cools the heat generating elements 150, e.g., by interacting with heat sink 155 (not shown in FIG. 3).

Referring to FIG. 4, an electronics rack 410 is shown with a plurality of electronics modules 100 mounted therein. The electronics modules 100 may be mounted such that the modules are directly above each other so that a maximum number of electronics modules may fit into the rack. In one example, the electronics modules 100 are network line cards, and the electronics rack 410 is configured to power the electronics modules 100 from the rear of the modules. A power supply may be included as part of the electronics rack 410, or may be external to the rack. In this example, the electronics rack is configured for front-to-back airflow. The electronics rack 410 may have one or more doors to access the interior of the rack, and may have one or more air filters to clean the air entering the rack.

Referring to FIG. 5, two electronics modules mounted adjacent to each other are shown to illustrate the effect of the bottom chamfer of the faceplate. The electronics modules are mounted (e.g., in an electronics rack 410) such that the chamfer 240 of the top electronics module substantially lines up with the intake slots of the bottom electronics module. Since the pressure drop of the airflow is typically dominated by the narrowest constriction, the chamfer 240 on the top electronics module opens up the constriction 510 in the path 520 of the air flow going in to the bottom electronics module. In one example, the chassis of the electronics rack in which the electronics modules are mounted may be designed such that the top module has at least as large of an area leading up to its intake slots as the bottom chamfer provides to each of the lower electronics modules.

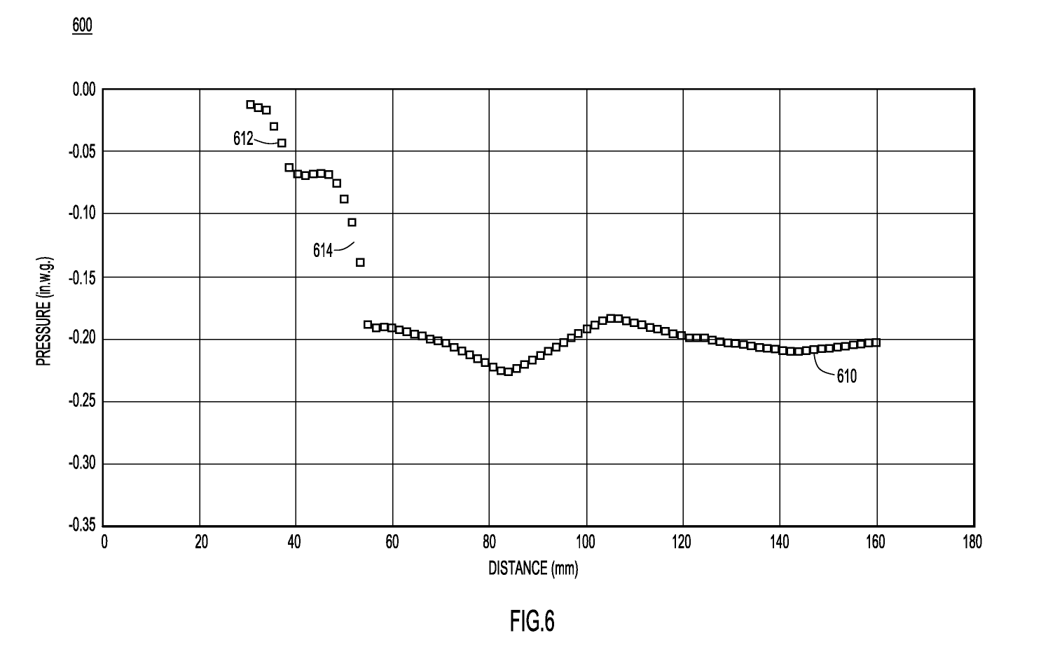

Referring to FIG. 6 (with reference to FIGS. 1A and 1B), a graph of a simulation of the gauge pressure of air as a function of the distance along the length of a network line card is shown. Data set 610 shows the air pressure at various points along the airflow path in cooling a network line card. The two main drops in pressure correlate to constrictions in the airflow path. In this example, the pressure drop at 612 corresponds to the constriction at the intake slots 115 where the airflow enters the section defined by the edges 210 and 212. The pressure drop at 614 corresponds to the dust shield 130 and constriction on the top side of the EMI shield 140. The total pressure drop resulting from adding the two pressure drops 612 and 614 is lower than the pressure drop that results from a narrower constriction at the intake slots in typical faceplates.

Another measure of the improved pressure drop characteristics is the increase in volumetric flow rate that a lower pressure drop allows. Table I shows the overall pressure drop and the volumetric flow rate of air through an individual electronics module with intake slots modified as described herein. The volumetric flow rate of air is given in units of cubic feet per minute (CFM) and the pressure is given in inches of water gauge (in. w.g.). The flow rate through the module with modified intake slots is approximately 20% higher than that typically achieved at normal operating conditions for network line cards.

TABLE I
Pressure drop and air flow rates for network modules
with improved intake slot design.

| | Vol. Flow Rate (CFM) | Pressure Drop (in. w.g.) |
|---|---|---|
| Module with Modified | 37.1 | 0.43 |
| Intake Slots | | |

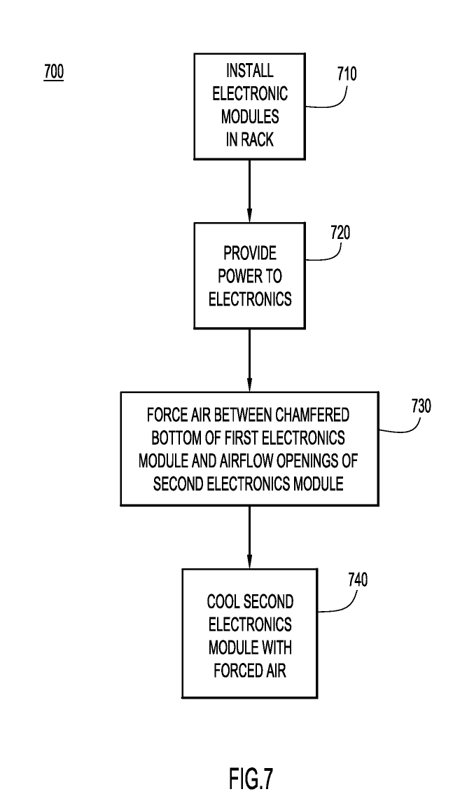

Referring to FIG. 7, an example process 700 of steps in using a faceplate with a chamfered bottom is shown. In step 710, a plurality of electronics modules are installed in an electronics rack. Power is provided to the electronics module in step 720, which may cause elements of the electronics module to begin generating heat. In step 730, air is forced between the chamfered bottom of the faceplate on a first electronics module and the intake slots of a second electronics module mounted below the first electronics module. Due to the chamfered bottom the area between the two electronics modules is larger enabling a larger flow volume of air to enter the intake slots of the second electronics module and cool the second electronics module in step 740.

In summary, the techniques presented herein maximize the projected intake area on the faceplates of electronics modules, such as network line cards, by enlarging and retracting the slots on top of the faceplate along with chamfering the faceplate's bottom edge. The increased projected intake area permits high air flow rates and lower pressure drops within the system. This allows more space for ports on the faceplate without sacrificing the ability to provide cooling capacity to heat generating elements, such as processors, memory, or application specific integrated circuits (ASICs).

In one example, the techniques presented herein provide for an apparatus comprising a frame and one or more heat generating elements supported by the frame. A plurality of ports are located at the front portion of the frame, and are electrically coupled to the heat generating elements. A faceplate is coupled to the front portion of the frame and includes one or more port openings to allow access to the ports and a plurality of airflow openings. Each of the airflow openings comprises a bottom edge aligned with the front portion of the frame and a top edge aligned with the top portion of the frame. The top edges of the airflow openings are set back a predetermined distance from the front portion of the frame.

In another example, the techniques presented herein provide for a system comprising an electronics rack to hold a plurality of electronics modules. Each of the electronics modules comprises a frame and one or more heat generating elements supported by the frame. A plurality of ports electrically coupled to the heat generating elements are located at the front portion of the frame. A faceplate coupled to the front portion of the frame further comprises one or more port openings to allow access to the ports, a plurality of airflow openings aligned with the top portion of the frame, and a chamfered bottom aligned with the bottom portion of the frame. A first electronics module selected from the plurality of electronics modules is mounted above a second electronics module, such that the chamfered bottom of the faceplate on the first electronics module is substantially aligned with the airflow openings of the faceplate on the second electronics module.

In a further example, the techniques presented herein provide for a method comprising installing a plurality of electronics modules in an electronics rack. Each of the electronics modules comprises one or more heat generating elements. The method also comprises providing power to the heat generating elements in the plurality of electronics modules. Air is forced between a chamfered bottom of a faceplate on a first electronics module selected from the plurality of electronics modules and a plurality of airflow openings in a second electronics module. The heat generating elements of the second electronics modules are cooled with the forced air.

The above description is intended by way of example only. Any material described is only an example of a material that may be used. Other materials can be substituted without leaving the scope of the present invention. It is also to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points or portions of reference and do not limit the present invention to any particular orientation or configuration. Further, the term “exemplary” is used herein to describe an example or illustration. Any embodiment described herein as exemplary is not to be construed as a preferred or advantageous embodiment, but rather as one example or illustration of a possible embodiment of the invention.

What is claimed is:

1. An apparatus comprising:
a frame comprising a front portion, a rear portion, a top portion, a bottom portion, a right side portion, and a left side portion;
one or more heat generating elements supported by the frame;
a plurality of ports located at the front portion of the frame, wherein the ports are electrically coupled to the heat generating elements;
a faceplate coupled to the front portion of the frame comprising:
one or more port openings to allow access to the ports; and
a plurality of airflow openings, each of the airflow openings comprising a bottom edge and a top edge, wherein the bottom edge is aligned with the front portion of the frame and the top edge is aligned with the top portion of the frame at a point a predetermined distance from the front portion of the frame.

2. The apparatus of claim 1, wherein the predetermined distance is at least 0.75 inches.

3. The apparatus of claim 1, further comprising a dust shield to prevent dust from entering the airflow openings.

4. The apparatus of claim 1, further comprising an electromagnetic interference (EMI) shield to minimize electromagnetic signals through the faceplate.

5. The apparatus of claim 4, wherein the EMI shield comprises an airflow passage to direct airflow from the airflow openings to a plurality of vent holes at an end opposite the airflow openings, the vent holes allowing air to enter the frame and cool the one or more heat generating elements.

6. The apparatus of claim 1, wherein the faceplate further comprises a chamfered portion aligned with the bottom portion of the frame.

7. The apparatus of claim 6, wherein the chamfered portion of the faceplate is substantially aligned with the airflow openings, such that the chamfered portion begins at the front portion of the frame and ends at a point substantially near the predetermined distance from the front of the frame.

8. A system comprising:
an electronics rack to hold a plurality of electronics modules;
each of the plurality of electronics modules comprising:
a frame comprising a front portion, a rear portion, a top portion, a bottom portion, a right side portion, and a left side portion;
one or more heat generating elements supported by the frame;
a plurality of ports located at the front portion of the frame, wherein the ports are electrically coupled to the heat generating elements;
a faceplate coupled to the front portion of the frame comprising:
one or more port openings to allow access to the ports;
a plurality of airflow openings aligned with the top portion of the frame; and
a chamfered bottom aligned with the bottom portion of the frame,
wherein a first electronics module selected from the plurality of electronics modules is mounted above a second electronics module selected from the plurality of electronics modules, such that the chamfered bottom of the faceplate on the first electronics module is substantially aligned with the airflow openings of the faceplate on the second electronics module.

9. The system of claim 8, wherein each of the airflow openings comprises a bottom edge and a top edge, wherein the bottom edge is aligned with the front portion of the frame and the top edge is aligned with the top portion of the frame at a point a predetermined distance from the front portion of the frame.

10. The system of claim 9, wherein the predetermined distance is at least 0.75 inches.

11. The system of claim 8, wherein each of the plurality of electronics modules further comprising a dust shield to prevent dust from entering the airflow openings.

12. The system of claim 8, wherein each of the plurality of electronics modules further comprises an electromagnetic interference (EMI) shield to minimize electromagnetic signals through the faceplate.

13. The system of claim 12, wherein the EMI shield comprises an airflow passage to direct airflow from the airflow openings to a plurality of vent holes at an end opposite to the airflow openings, the vent holes allowing air to enter the frame and cool the one or more heat generating elements.

14. The system of claim 8, further comprising one or more fans to drive airflow through the plurality of electronics modules.

15. The system of claim 8, wherein the plurality of electronics modules comprise a plurality of network line cards.

16. A method comprising:
installing a plurality of electronics modules in an electronics rack, each electronics module comprising one or more heat generating elements;
providing power to the heat generating elements in the plurality of electronics modules;
forcing air between a chamfered bottom of a faceplate on a first electronics module selected from the plurality of electronics modules and a plurality of airflow openings in a second electronics module selected from the plurality of electronics modules; and
cooling the one or more heat generating elements of the second electronics module with the forced air.

17. The method of claim 16, wherein installing the plurality of electronics modules comprising aligning the chamfered bottom of the faceplate of the first electronics module with the airflow openings of the second electronics module.

18. The method of claim 16, further comprising installing a dust shield on the plurality of airflow openings to remove dust from the forced air.

19. The method of claim 16, further comprising installing an electromagnetic interference (EMI) shield to minimize electromagnetic signals through the faceplate of the second electronics module.

20. The method of claim 19, further comprising directing airflow from the airflow openings in the second electronics module through the EMI shield to a plurality of vent holes at an end opposite to the airflow openings, the vent holes allowing air to cool the one or more heat generating elements in the second electronics module.
